(19) United States
(12) Patent Application Publication
(10) Pub. No.: US 2017/0284864 A1
(43) Pub. Date: Oct. 5, 2017

(54) OPTICAL PROXIMITY SENSOR AND MANUFACTURING METHOD THEREOF

(71) Applicant: TING-YI CHEN, TAOYUAN CITY (TW)

(72) Inventor: TING-YI CHEN, TAOYUAN CITY (TW)

(21) Appl. No.: 15/145,917

(22) Filed: May 4, 2016

(30) Foreign Application Priority Data
Mar. 30, 2016 (TW) 105109956

(51) Int. Cl. G01J 1/44; G01J 1/02; H01S 5/183; G01J 1/04; H01L 25/16; H01S 5/022; G01J 1/42; G01J 1/08

(52) U.S. Cl. CPC G01J 1/44; G01J 1/4204; G01J 1/0204; G01J 1/08; G01J 1/04; H01L 25/167; H01L 25/165; H01S 5/02248; H01S 5/183

(57) ABSTRACT

A complex optical proximity sensor includes a substrate, a light emitter coupled to the substrate, an application-specific integrated circuit chip coupled to the substrate with a proximity sensor thereon, a barrier disposed between the application-specific integrated circuit chip and the light emitter, and an ambient light detection chip manufactured in advance and then coupled to the application-specific integrated circuit chip thereon with a pre-determined height. Also, with the manufacturing method of the complex optical proximity sensor, the detection angle of the ambient light is thereby maximized and the one of the proximity sensor is thereby minimized.

### BACKGROUND OF THE INVENTION

### 1. Field of the Invention

The invention relates to an optical proximity sensor and a manufacturing method thereof that has a hole as an opening to be installed on a front surface of a smartphone with a small aperture, so as to minimize a detection angle of the proximity and maximize a detection angle of ambient light detection in the meantime.

### 2. Description of the Related Art

Smart mobile devices such as smartphones usually have an ambient light sensor (ALS) for ambient light detection to adjust brightness of the touchscreen for energy-saving; such devices also have a proximity sensor (PS) and a light emitter for proximity detection to automatically close the touchscreen in case of inadvertent operations when a user's face is close to the touchscreen during a call. The ALS and PS are both applications of light detection and therefore can be integrated into one package with the light emitter for less installation space, less manufacturing materials, and combined arrangement for circuits. The ALS and PS are usually disposed aside a display panel of a smart mobile device. Referring to FIGS. 1A and 1B, a smartphone P therefore has different openings on a front panel thereof for different ALS and PS structures—an elongated hole G₁ as in FIG. 1A or a circular hole G₂ as in FIG. 1B.

As smart mobile devices are getting more popular, the appearance design is getting more important. Nowadays it is preferred to have an aperture as small as possible on a front surface of smart mobile devices, and the structures must share one aperture on a smart mobile device if they are to be integrated. However, ALS and PS have different factors to be considered in application. A detection angle of the ALS has to be as wide as possible while a detection angle of the PS and light emitter has to be as narrow as possible. The opening on the smartphone P was an elongated hole G₁ as shown in FIG. 1A, and then it was designed to be a circular hole G₂ as shown in FIG. 1B to meet a favorable design expected by the consumers regardless of a consequence of narrower detection angle for ambient light.

A structure of an optical proximity sensing package 10 is illustrated in FIG. 2 in which ALS and PS are arranged laterally. The optical proximity sensing package 10 includes a substrate 11, an infrared (IR) LED 12 disposed on the substrate 11, and a detection unit 13 disposed on the substrate 11 with a proximity sensor 131 and an ambient light sensor 132 thereon. A barrier 14 is arranged between the IR LED 12 and the detection unit 13 to avoid interferences from the IR LED 12 to the proximity sensor 131. When the IR LED 12 emits light to be reflected by an object O to the proximity sensor 131, a proximity detection angle θₐ₁ is formed; the proximity sensor 131 is disposed near the left of the ambient light sensor 132 so that the proximity detection angle θₐ₁ cannot be too narrow. The ambient light sensor 132 has the barrier 14 blocking its detection angle; therefore the ambient light detection angle θ_{b1} cannot be too wide. With such arrangement, the proximity detection angle θₐ₁ and the ambient light detection angle θ_{b1} are coordinated to be a medium number for operation. Such structure has a distance from the IR LED 12 to the proximity sensor 131 and the ambient light sensor 132, therefore requires an elongated hole G₁ to be arranged on a front surface of the smartphone P with a large aperture T₁.

FIG. 3 illustrated a package-on-package (POP) optical sensor 20 disclosed in U.S. Pat. No. 8,143,608. The POP optical sensor 20 includes an IR light emitter 211 disposed on a first substrate 21, a light detector 221 disposed on a second substrate 22 together with an ambient light detector 222, and an integrated circuit disposed on a third substrate 23 and encapsulated by an overmolding material 24, including a light emitter driver circuit, a light detection circuit, and an ambient light detection circuit. The first and second substrates 21, 22 both have wire bond pads 212, 223, 224, and the third substrate 23 further includes at least first, second and third sets of wire bond pads 231, 232, 233 uncovered by the overmolding material 24 and electrically connected to the integrated circuit. The IR light emitter 211 is electrically connected to the light emitter driver circuit via the wire bond pads 212 on the first substrate 21, a wire 25, and the first set of wire bond pads 231; the light detector 221 and the ambient light detector 222 are electrically connected to the light detection circuit and ambient light detection circuit via the wire bond pads 223, 224 on the second substrate 22, a wire 25, and the second and third set of wire bond pads 232, 233. A first molded IR pass component 26 including a lens 261 by molding is further disposed on and covers the IR light emitter 211. A second molded IR pass component 27 including a lens 271 by molding is further disposed on and covers the light detector 221 and ambient light detector 222. A molded IR cut component (not shown) is further disposed between partial of the third substrate 23 and the first and second IR pass component 26, 27 and covers the mentioned area.

With the structures disclosed, the IR light emitter 211 would not interfere with the light detector 221 and a proximity detection angle θₐ₂ is formed when the IR light emitter 211 emits light which is reflected by an object O to the light detector 221. The proximity detection angle θₐ₂ remains the same with comparison to the conventional optical proximity sensor package 10 since the ambient light detector 222 is disposed between the IR light emitter 211 and the light detector 221; but a detection angle θ_{b2} for ambient light L is wider without a barrier disposed in-between. However, such structure is still in lateral arrangement and still has quite a distance between the IR light emitter 211 and the light detector 221. Therefore, it still requires an elongated hole G₁ arranged on a front surface of a smartphone P with a large aperture T₁.

FIG. 4 illustrated a photosensor chip package structure 30 disclosed in U.S. Pat. No. 8,716,722. The package structure includes an opaque substrate 31, a light emitting chip 32, and a photosensor chip 33 including an ambient light detection unit 331 and a proximity sensor 332.

The opaque substrate 31 has a first basin 311 on a surface thereof, a second basin 312 on a reverse surface thereof, and a light guiding channel 313 connecting through the first basin 311 and the second basin 312. The second basin 312 and the light guiding channel 313 both have a reflection layer 34. The light emitting chip 32 is disposed in the first basin 311 and covered by a translucent first sealant material 35 filled therein. The photosensor chip 33 is disposed in the second basin 312, fixed by a plurality of metal blocks 37, and covered by a translucent second sealant material 36 which is also filled in the light guiding channel 313.

With the structures disclosed, the light emitting chip 32 would not interfere with the proximity sensor 332. When a light emitted by the light emitting chip 32 is reflected by an object O to the proximity sensor 332, a proximity detection angle θₐ₃ is formed; and the photosensor chip 33 receives ambient light L by the light guiding channel 313 with a pre-determined arrangement of detection angle θ_{b3} for operation. In addition, the first basin 311 overlaps on partial of the second basin 312 so that the distance from the light emitting chip 32 to the ambient light detection unit 331 and proximity sensor 332 is improved to be shortened, resulting in narrow detection angle of the proximity detection and the ambient light detection. Such structure also enables a favorable circular hole G₂ to be arranged on a front surface of a smartphone P with a small aperture T₂. Nevertheless, the ambient light detection range becomes a defect since the detection angle cannot reach a suitable and efficient range for operation.

On the other hand, there is another structure to have a module including the PS and light emitter operated through a circular opening and another module with ALS operated through another circular opening on a front surface of a smartphone. The appearance may still be favorable to the consumers, but such structure requires a large number of volumes to be installed on a smartphone, resulting in another defect for improvement.

All in all, it is desirable to improve the defects described above and find a manufacturing method that would allow a maximized detection angle for ALS structures—in the prior cases, the ambient light sensor 132, the ambient light detector 222, and the ambient light detection unit 331—and a minimized detection angle for PS structures—in the prior cases, the IR LED 12, the IR light emitter 211, and the light emitting chip 32, and that would allow the structures to share one small circular opening on a front surface of a smart mobile device.

### SUMMARY OF THE INVENTION

It is a primary object of the present invention to provide an optical proximity sensor and a manufacturing method thereof that has an isolated ambient light detection chip as an ambient light sensor (ALS); it is also isolated from a circuit of the proximity sensor (PS) so that the distance from the ambient light detection chip to a light emitter and from the proximity sensor to the light emitter are both shortened. Also, with a circular opening, the present invention simply needs a small aperture on a front surface of a smartphone for sophisticatedly detection with a minimized detection angle of the PS structure and a maximized detection angle of the ALS structure.

In order to achieve the objects above, the complex optical proximity sensor comprises a substrate; a light emitter coupled to the substrate thereon; an application-specific integrated circuit (ASIC) chip coupled to the substrate thereon with a proximity sensor installed on the chip and a barrier disposed between the chip and the light emitter; and an ambient light detection chip separately manufactured and then coupled to the application-specific integrated circuit chip with a pre-determined height thereon; said ambient light detection chip being arranged without obstructing the application-specific integrated circuit chip to form a complex optical proximity sensor.

Whereby a light is emitted from the light emitter and reflected to the proximity sensor for detection with the barrier arranged at a pre-determined height to prevent interferences from the emitted light to the proximity sensor and the ambient light detection chip is manufactured separately with a height in accordance with the height of the barrier to ensure the barrier not to obstruct the ambient light detection chip and to minimize a detection angle of the proximity sensor and maximize a detection angle of the ambient light detection chip.

Further with structures disclosed above, the ambient light detection chip is a chip for ambient light detection, RGB color detection, or ultraviolet (UV) detection, and the light emitter is a LED, a laser diode (LD), or a vertical-cavity surface-emitting laser (VCSEL).

The substrate is either a ceramic substrate or a PCB, and the application-specific integrated circuit chip has a plurality of first connect points to be coupled to a plurality of second connect points on the light emitter. The substrate further has a plurality of bond pads arranged under a bottom thereof to be coupled to the application-specific integrated circuit chip and the light emitter, making the complex optical proximity sensor a surface-mount device. A plurality of transparent packages is disposed on the substrate for the ambient light detection chip, the application-specific integrated circuit chip and the light emitter to be separately encapsulated therein, and a non-transparent package is disposed on the substrate for the barrier to be encapsulated therein. The material of transparent packages is made of lens.

As stated above, the ambient light detection chip is isolated and disposed on the ASIC chip with a pre-determined height thereon to maximize the detection angle for ambient light, and the proximity sensor is coupled to and installed on the ASIC chip to minimize the detection angle for proximity. The present invention thereby integrates the structures into one complex device with a circular opening that can be applied to a small aperture on a front surface of a smartphone.

### BRIEF DESCRIPTION OF THE DRAWINGS

FIG. 1A is a schematic diagram of a smartphone with an elongated hole in the prior art;

FIG. 1B is a schematic diagram of a smartphone with a circular hole in the prior art;

FIG. 2 is a schematic diagram illustrating a package structure of an optical proximity sensor in the prior art;

FIG. 3 is a schematic diagram illustrating a package-on-package structure of an optical proximity sensor in the prior art;

FIG. 4 is a schematic diagram illustrating a package structure of a photo sensor chip in the prior art;

FIG. 5 is a top plan view of the present invention;

FIG. 6 is a bottom plan view of the present invention;

FIG. 7A is a sectional view along ling 7A-7A in FIG. 5;

FIG. 7B is a schematic diagram of the present invention;

FIG. 8 is a practical application view of the present invention; and

FIG. 9 is a curve diagram of angular displacement comparison between the present invention and the prior art in ambient light detection.

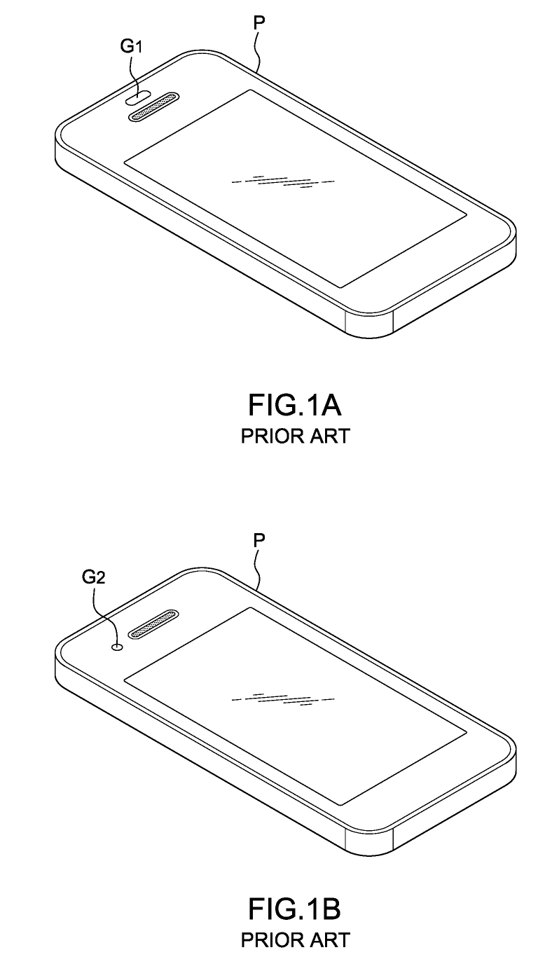

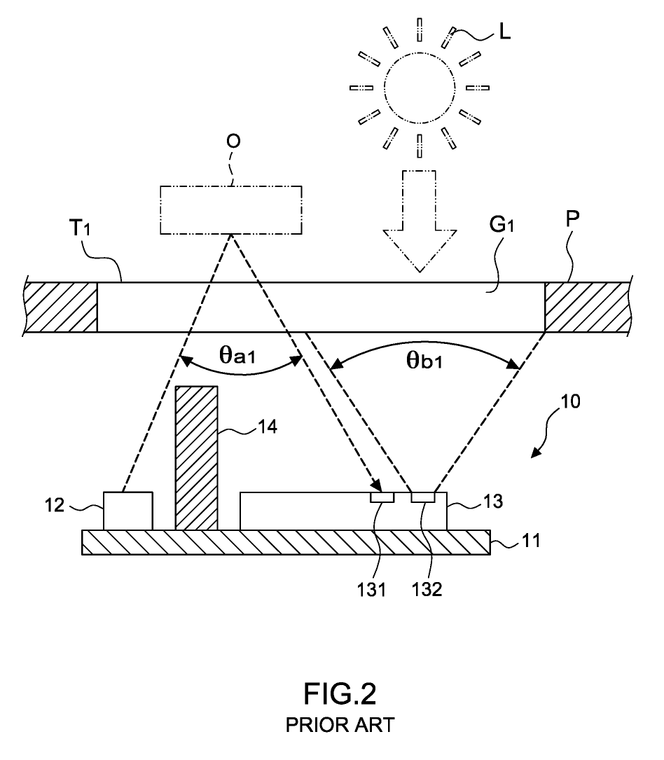

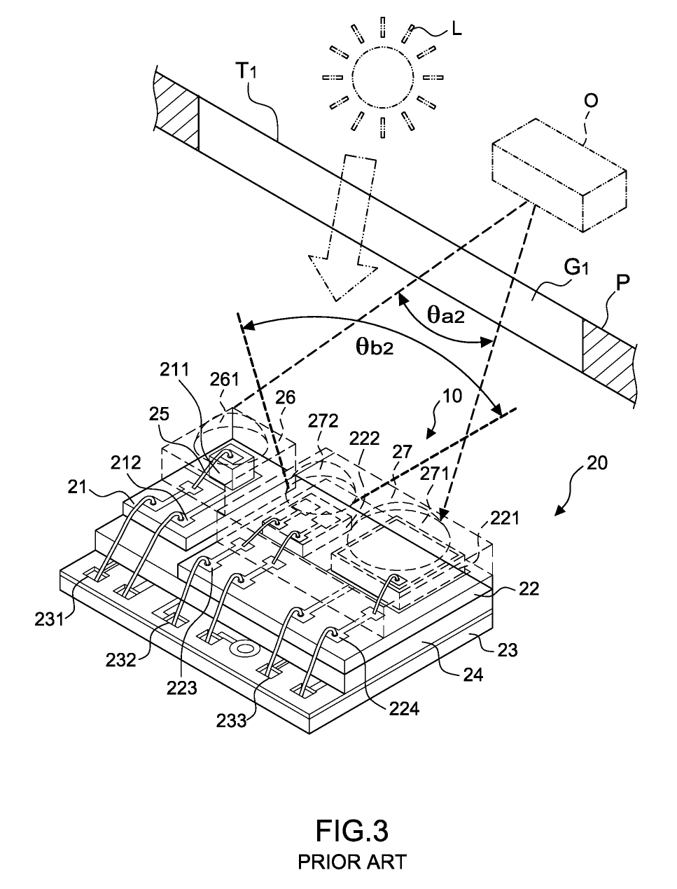

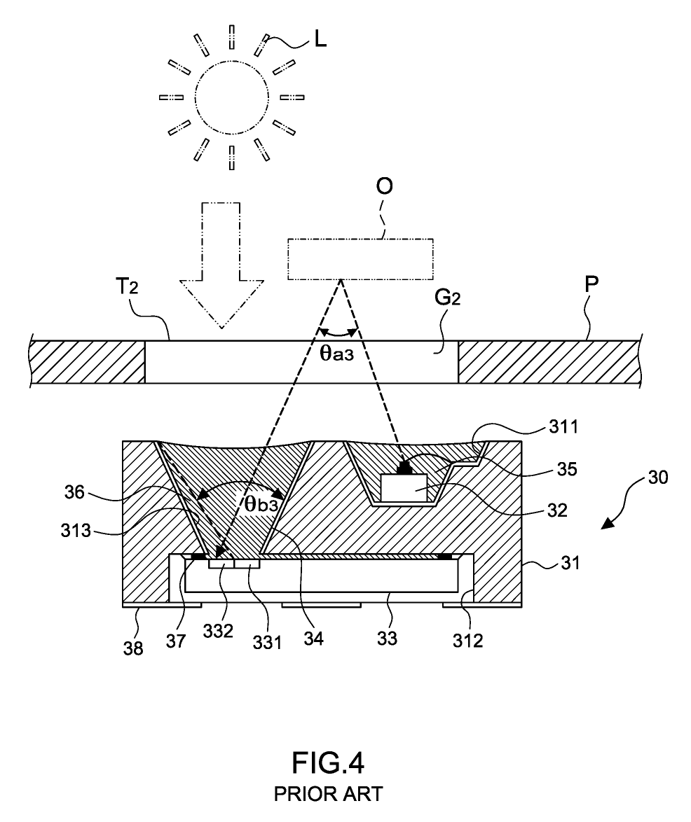

### DETAILED DESCRIPTION OF THE PREFERRED EMBODIMENT

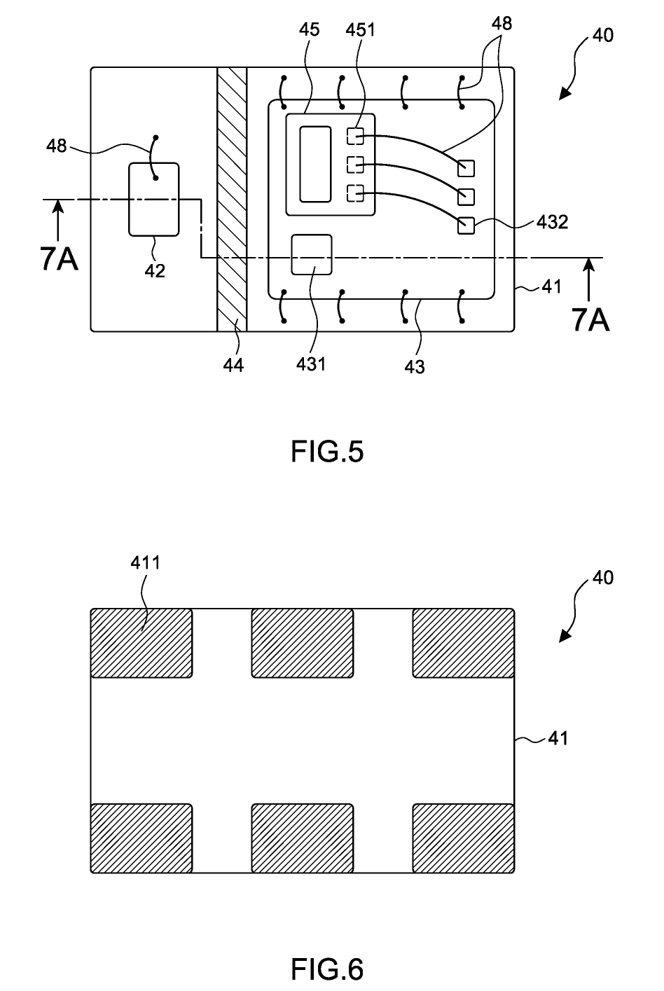

FIGS. 5-9 illustrated a preferred embodiment of the present invention—a complex optical proximity sensor 40 that has a minimum detection angle for proximity θₐ₄ and a maximum detection angle for ambient light θ_{b4}.

In the embodiment, the complex optical proximity sensor 40 includes a substrate 41, a light emitter 42, an application-specific integrated circuit (ASIC) chip 43, and an ambient light detection chip 45.

The substrate 41 is a ceramic substrate or a PCB, but it is not limited to such application. The light emitter 42 is coupled to the substrate 41 thereon by an electric wire 48. In the embodiment, the light emitter 42 is a LED, a laser diode (LD), or a vertical-cavity surface-emitting laser (VCSEL), but it is not limited to such application.

The ASIC chip 43 is coupled to the substrate 41 thereon by an electric wire 48 and has a proximity sensor (PS) 431 installed on the ASIC chip 43. A barrier 44 is further disposed between the ASIC chip 43 and the light emitter 42. In the embodiment, the ASIC chip 43 has a plurality of first connect points 432 to be coupled to a plurality of second connect points 451 on the light emitter 42 ASIC chip 43 via an electric wire 48.

The ambient light detection chip 45 is separately manufactured and then coupled by an electric wire 48 to the ASIC chip 43 with a pre-determined height thereon to form the complex optical proximity sensor 40 without obstructing the proximity sensor 431 on the ASIC chip 43. In the embodiment, the ambient light detection chip 45 is a chip for ambient light detection, RGB color detection, or ultraviolet (UV) detection.

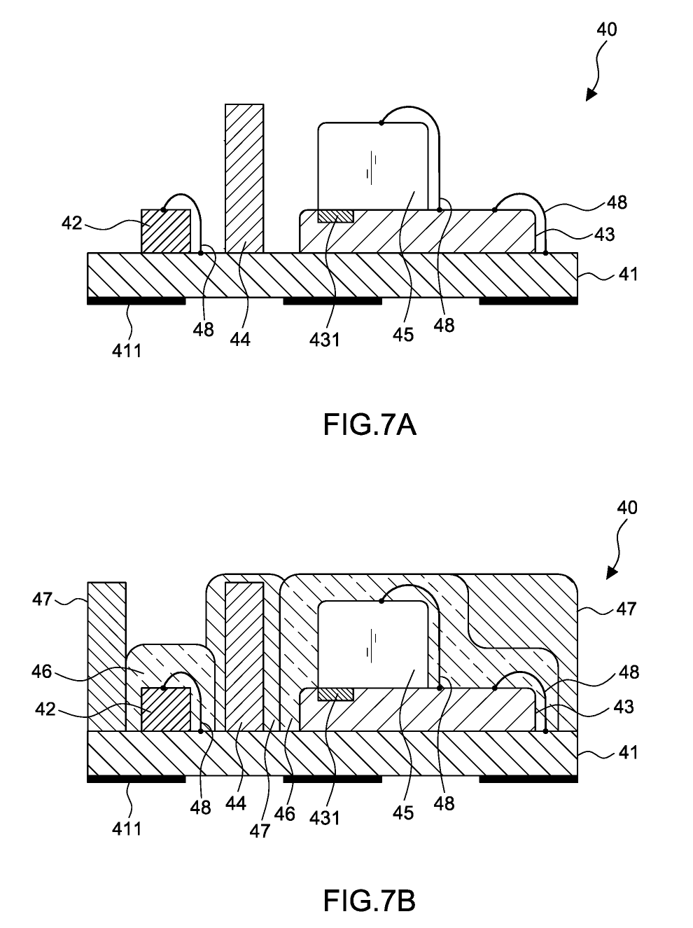

As shown in FIGS. 5 and 7A, the ambient light detection chip 45 is separately manufactured and then disposed on and coupled to the ASIC chip 43 to enable adjustment of a distance to the barrier 44 without changing or affecting the circuits on the ASIC chip 43. Further referring to FIG. 6, the substrate 41 has a plurality of bond pads 411 arranged under a bottom thereof to be coupled to the ASIC chip 43 and the light emitter 42, making the complex optical proximity sensor 40 a surface-mount device.

FIG. 7B shows a plurality of transparent packages 46 is disposed on the substrate 41 for the ambient light detection chip 45, the ASIC chip 43 and the light emitter 42 to be separately encapsulated therein, and a non-transparent package 47 is disposed on the substrate 41 for the barrier 44 to be encapsulated therein. In another embodiment, the material of the transparent packages 46 is made of lens.

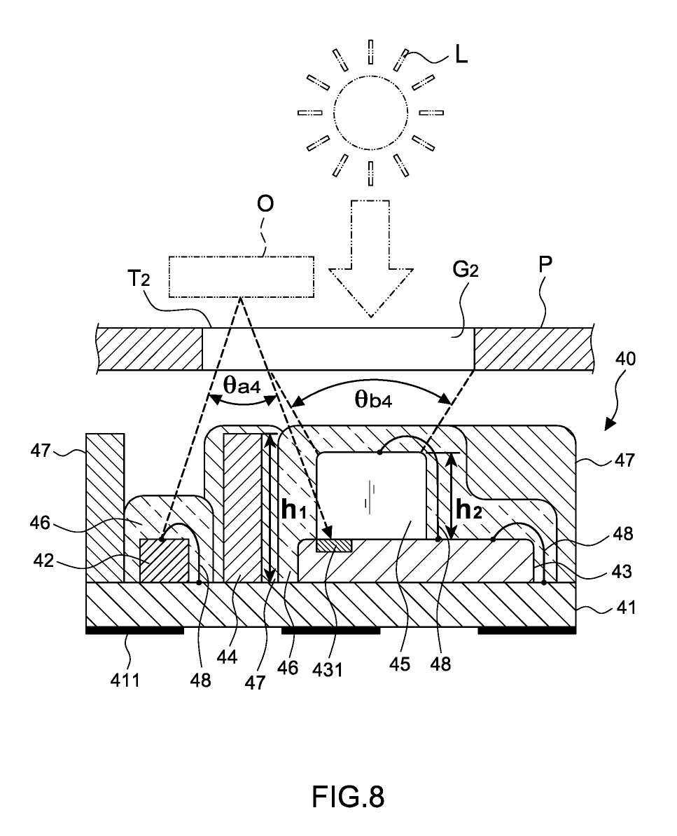

As illustrated in FIG. 8, a light is emitted from the light emitter 42 and reflected by an object O to the proximity sensor 431 for detection with the barrier 44 at a pre-determined height h₁ to prevent interferences from the emitted light to the proximity sensor 431. In addition, the ambient light detection chip 45 is manufactured separately with a height h₂ in accordance with the height h₁ of the barrier 44 to ensure the barrier 44 not to obstruct the ambient light detection chip 45 in ambient light L detection, thereby minimizing the detection angle θₐ₄ of the proximity sensor 431 and maximizing the detection angle θ_{b4} of the ambient light detection chip 45. With a circular opening as an aperture G₂ on a front surface of a smartphone P, the ASIC chip 43 is able to receive the light emitted from the light emitter 42 and ambient light L to control the operation of the ambient light detection chip 45, the light emitter 42 and the proximity sensor 431.

To further explain the differences between the technologies in the prior art and the present invention in aperture sizes, detection angle θₐ of the proximity sensor, and detection angle θ_{b} of ambient light detection, a table chart is disclosed below.

| | An optical | | | |
|---|---|---|---|---|
| | proximity | A POP | A photosensor | The |
| | sensing | optical | chip package | present |
| | package | sensor | structure | invention |
| Aperture of | Large | Large | Small | Small |
| an opening | | | | |
| Proximity | Medium | Medium | Narrow | Narrow |
| detection angle | | | | |
| θa | | | | |
| Ambient light | Medium | Wide | Narrow | Wide |
| detection angle | | | | |
| θb | | | | |

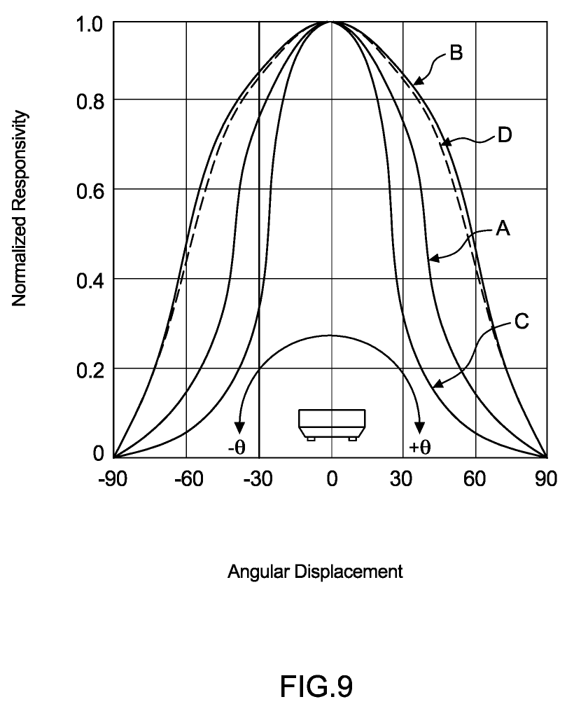

With reference to FIG. 9, further analysis and clarification of the differences are described as following.

1. Curve A shows an angular displacement of ambient light detection in an optical proximity sensing package structure. A PS thereof is disposed close to the left of an ALS thereof so the proximity detection angle cannot be too narrow, and the ALS cannot reach a wide angle for ambient light detection either due to arrangement of a barrier; plus, such structure has the ALS and PS arranged laterally. Therefore, it requires an elongated hole to be arranged on a front surface of a smartphone with a large aperture.

2. Curve B shows an angular displacement of ambient light detection in a POP optical sensor. The ambient light detection angle can be wide without a blocking element, but the proximity detection angle remains unchanged comparing to the structure in an optical proximity sensing package. Therefore, it still requires an elongated hole on a front surface of a smartphone with a large aperture.

3. Curve C shows an angular displacement of ambient light detection in a photosensor chip package structure. The proximity detection angle and the ambient light detection angle become narrower with the PS and ALS thereof disposed in different basins. Thus an opening on a smartphone for its application is a circular hole with a small aperture, but the ambient light detection angle is not suitable for operation.

4. Curve D shows an angular displacement of ambient light detection in the present invention. With the ambient light detection chip 45 isolated and disposed on the ASIC chip 43 with a pre-determined height thereon, the detection angle for ambient light is maximized, and with the proximity sensor 431 coupled to and installed on the ASIC chip 43, the detection angle for proximity is minimized. Moreover, such structure can operate by a circular hole as the opening with a small aperture on a smart mobile device without any compromise in detection angles.

1. A complex optical proximity sensor, comprising:
a substrate;
a light emitter coupled to the substrate;
an application-specific integrated circuit chip coupled to the substrate with a proximity sensor installed on the chip and a barrier disposed between the chip and the light emitter; and
an ambient light detection chip separately manufactured and then coupled to the application-specific integrated circuit chip, the ambient light detection chip extending to a pre-determined height relative to a laterally extended surface of the application-specific integrated circuit chip; said ambient light detection chip being offset in position from the proximity sensor to be laterally spaced therefrom and to thereby form a complex optical proximity sensor;
whereby a light is emitted from the light emitter and reflected to the proximity sensor for detection; the barrier is arranged at a pre-determined height to prevent interference from the emitted light to the proximity sensor and to minimize a detection angle of the proximity sensor; and the ambient light detection chip is manufactured separately with a height in accordance with the height of the barrier to maximize a detection angle of the ambient light detection chip.

2. The complex optical proximity sensor as claimed in claim 1, wherein the ambient light detection chip is a chip for ambient light detection, RGB color detection, or ultraviolet (UV) detection.

3. The complex optical proximity sensor as claimed in claim 1, wherein the light emitter is a LED, a laser diode (LD), or a vertical-cavity surface-emitting laser (VCSEL).

4. The complex optical proximity sensor as claimed in claim 1, wherein the substrate is either a ceramic substrate or a PCB, and the application-specific integrated circuit chip has a plurality of first connect points to be coupled to a plurality of second connect points on the ambient light detection chip.

5. The complex optical proximity sensor as claimed in claim 4, wherein the substrate has a plurality of bond pads arranged under a bottom thereof to be coupled to the application-specific integrated circuit chip and the light emitter, making the complex optical proximity sensor a surface-mount device.

6. The complex optical proximity sensor as claimed in claim 1, wherein the substrate has a plurality of transparent packages for the ambient light detection chip, the application-specific integrated circuit chip and the light emitter to be separately encapsulated therein.

7. The complex optical proximity sensor as claimed in claim 1, wherein the substrate further has a non-transparent package for the barrier to be encapsulated therein.

8. The complex optical proximity sensor as claimed in claim 6, wherein the material of transparent packages is made of lens.

9. A manufacturing method of the complex optical proximity sensor as claimed in claim 1, comprising:
a) providing a substrate;
b) providing a light emitter coupled to the substrate;
c) providing an application-specific integrated circuit chip coupled to the substrate with a proximity sensor installed on the chip and a barrier disposed between the chip and the light emitter; and
d) providing an ambient light detection chip coupled to the application-specific integrated circuit chip, the ambient light detection chip extending to a pre-determined height relative to a laterally extended surface of the application-specific integrated circuit chip; said ambient light detection chip being offset in position from the proximity sensor to be laterally spaced therefrom and to thereby form a complex optical proximity sensor;
whereby a light is emitted from the light emitter and reflected to the proximity sensor for detection; the barrier is arranged at a pre-determined height to prevent interferences from the emitted light to the proximity sensor and to minimize a detection angle of the proximity sensor; and the ambient light detection chip is manufactured separately and has a height in accordance with the height of the barrier to maximize a detection angle of the ambient light detection chip.

10. The method as claimed in claim 9, wherein the substrate is either a ceramic substrate or a PCB to be coupled to the application-specific integrated circuit chip and the light emitter, and the application-specific integrated circuit chip has a plurality of first connect points to be coupled to a plurality of second connect points on the ambient light detector chip.
